(19) United States
(12) Patent Application Publication
(10) Pub. No.: US 2008/0011601 A1
(43) Pub. Date: Jan. 17, 2008

(54) COOLED ANODES

(75) Inventors: ALLEN KA-LING LAU, Cupertino, CA (US); Makoto Inagawa, Palo Alto, CA (US); Bradley O. Stimson, Monte Sereno, CA (US); Akihiro Hosokawa, Cupertino, CA (US)

Correspondence Address: PATTERSON & SHERIDAN, LLP, 3040 POST OAK BOULEVARD, SUITE 1500, HOUSTON, TX, 77056, US

(73) Assignee: Applied Materials, Inc.

(21) Appl. No.: 11/771,366

(22) Filed: Jun. 29, 2007

Related U.S. Application Data
(60) Provisional application No. 60/807,391, filed on Jul. 14, 2006.

(51) Int. Cl. C23C 14/35

(52) U.S. Cl. 204/192.1; 204/298.12; 204/298.16

(57) ABSTRACT

A physical vapor deposition (PVD) apparatus and a PVD method are disclosed. Extending an anode across the processing space between the target and the substrate may increase deposition uniformity on a substrate. The anode provides a path to ground for electrons that are excited in the plasma and may uniformly distribute the electrons within the plasma across the processing space rather than collect at the chamber walls. The uniform distribution of the electrons within the plasma may create a uniform deposition of material on the substrate. The anodes may be cooled with a cooling fluid to control the temperature of the anodes and reduce flaking. The anodes may be disposed across the process space perpendicular to the long side of a magnetron that may scan in two dimensions across the back of the sputtering target. The scanning magnetron may reduce localized heating of the anode.

### CROSS-REFERENCE TO RELATED APPLICATIONS

This application claims benefit of U.S. provisional patent application Ser. No. 60/807,391 (APPM/11277L), filed Jul. 14, 2006, which is herein incorporated by reference.

### BACKGROUND OF THE INVENTION

1. Field of the Invention

Embodiments of the present invention generally relate to a physical vapor deposition (PVD) system for large area substrates.

2. Description of the Related Art

PVD using a magnetron is one method of depositing material onto a substrate. During a PVD process a target may be electrically biased so that ions generated in a process region can bombard the target surface with sufficient energy to dislodge atoms from the target. The process of biasing a target to cause the generation of a plasma that causes ions to bombard and remove atoms from the target surface is commonly called sputtering. The sputtered atoms travel generally toward the substrate being sputter coated, and the sputtered atoms are deposited on the substrate. Alternatively, the atoms react with a gas in the plasma, for example, nitrogen, to reactively deposit a compound on the substrate. Reactive sputtering is often used to form thin barrier and nucleation layers of titanium nitride or tantalum nitride on the substrate.

Direct current (DC) sputtering and alternating current (AC) sputtering are forms of sputtering in which the target is biased to attract ions towards the target. The target may be biased to a negative bias in the range of about −100 to −600 V to attract positive ions of the working gas (e.g., argon) toward the target to sputter the atoms. Usually, the sides of the sputter chamber are covered with a shield to protect the chamber walls from sputter deposition. The shield may be electrically grounded and thus provide an anode in opposition to the target cathode to capacitively couple the target power to the plasma generated in the sputter chamber.

During sputtering, material may sputter and deposit on the exposed surfaces within the chamber. When the temperature fluxuates from a processing temperature to a lower, non-processing temperature, material that has deposited on the exposed surfaces of the chamber may flake off and contaminate the substrate.

When depositing thin films over large area substrates such as glass substrates, polymer substrates, flat panel display substrates, solar panel substrates, and other suitable substrates, uniform deposition on the substrate can be difficult. Therefore, there is a need in the art to reduce flaking in PVD chambers, while also uniformly depositing material onto a substrate.

### SUMMARY OF THE INVENTION

The present invention generally comprises a PVD apparatus and a PVD method. Extending an anode across the processing space between the target and the substrate may increase deposition uniformity on a substrate. The anode provides a path to ground for electrons that are excited in the plasma and may uniformly distribute the electrons within the plasma across the processing space rather than collect at the chamber walls. The uniform distribution of the electrons within the plasma may create a uniform deposition of material on the substrate. The anodes may be cooled with a cooling fluid to control the temperature of the anodes and reduce flaking. The anodes may be disposed across the process space perpendicular to the long side of a magnetron that may scan in two dimensions across the back of the sputtering target. The scanning magnetron may reduce localized heating of the anode.

In one embodiment, a physical vapor deposition apparatus is disclosed. The apparatus comprises a chamber body having a processing space therein, one or more targets, a substrate support, and one or more anodes positioned between the one or more targets and the substrate support. The one or more anodes each comprise an inner and outer wall, wherein the inner wall defines a fluid flow path through which cooling fluid flows while in contact with the inner wall.

In another embodiment, an anode assembly is disclosed. The anode assembly comprises an anode body having an outer wall, a hollow passage bounded by an inner wall, a first end having a cooling fluid inlet coupled thereto, and a second end having a fluid outlet coupled thereto.

In another embodiment, a physical vapor deposition method is disclosed. The method comprises positioning a susceptor within a chamber opposite a sputtering target to define a processing space between the target and the susceptor, sputtering material from the target to create a plasma, providing a path to ground within the processing space wherein the path to ground spans an area across the processing space and comprises an inner wall and an outer wall, and flowing a cooling fluid within the path to ground while in contact with the inner wall.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-section view of a PVD apparatus 100 according to one embodiment of the invention.

FIG. 2 is a top view of one embodiment of a PVD apparatus 100 incorporating cooled anodes.

FIG. 3A is a top view of an anode 134 passing through the dark space shield 136 according to one embodiment of the invention.

FIG. 3B is a cross section view of the anode 134 and anode mounting bracket 144 according to one embodiment of the invention.

FIG. 4 is a drawing of the cooling assembly 150 according to one embodiment of the invention.

FIGS. 5A and 5B are schematic views of magnetrons in relation to cooled anodes according to embodiments of the invention.

FIG. 6 is a schematic view of a scanning pattern for a magnetron according to one embodiment of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally comprises a PVD apparatus and a PVD method. Extending an anode across the processing space between the target and the substrate may increase deposition uniformity on a substrate. The anode provides a path to ground for electrons that are excited in the plasma and may uniformly distribute the electrons within the plasma across the processing space rather than collect at the chamber walls. The uniform distribution of the electrons within the plasma may create a uniform deposition of material on the substrate. The anodes may be cooled with a cooling fluid to control the temperature of the anodes and reduce flaking. The anodes may be disposed across the process space perpendicular to the long side of a magnetron that may scan in two dimensions across the back of the sputtering target. The scanning magnetron may reduce localized heating of the anode.

The invention is illustratively described and may be used in a PVD system for processing large area substrates, such as a PVD system, available from AKT®, a subsidiary of Applied Materials, Inc., Santa Clara, Calif. However, it should be understood that the sputtering target may have utility in other system configurations, including those systems configured to process large area round substrates and those produced by other manufacturers.

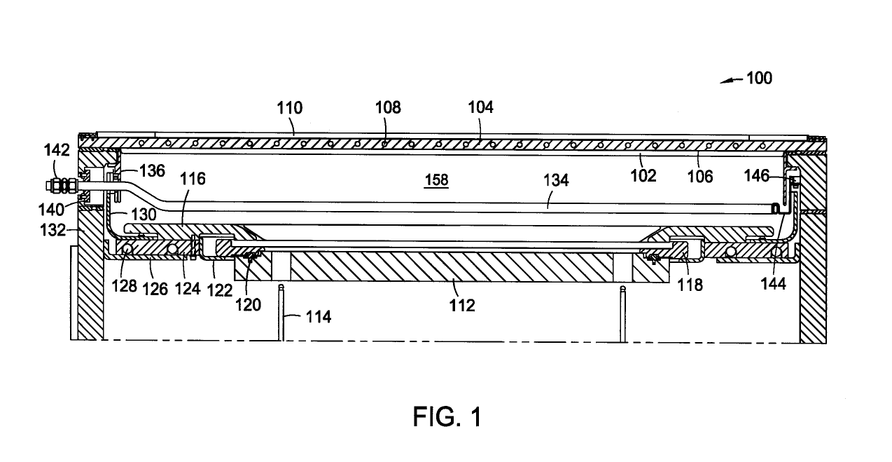

FIG. 1 is a cross-section view of a PVD apparatus 100 according to one embodiment of the invention. The apparatus 100 includes a sputtering target 102 bonded to a backing plate 104 by a bonding layer 106. The target 102 sits opposite a susceptor 112 across a processing space 158. Within the backing plate 104, cooling channels 108 may be present that help provide a uniform temperature across the target 102. A dark space shield 136 may surround the target 102. A magnetron 110 may be present behind the backing plate 104.

As the demand for larger flat panel displays increases, so must the substrate size. With increasing substrate size comes various challenges. Among those challenges is uniform deposition. Electrons within the sputtering plasma are attracted to elements within the apparatus 100 that are grounded. Traditionally, the chamber walls 132 and the susceptor 112 or substrate support are grounded and thus, function as an anode in opposition to the sputtering target 102, which functions as the cathode.

The grounded chamber walls 132 functioning as an anode attract electrons from the plasma and hence, may tend to create a higher density of plasma near the chamber walls 132. A higher density of plasma near the chamber walls 132 may increase the deposition on the substrate near the chamber walls 132 and decrease the deposition away from the chamber walls 132. The grounded susceptor 112, on the other hand, also functions as an anode. The susceptor 112 may span a significant length of the processing space 158. In many cases, the susceptor 112 encompasses an area as large as the substrate. Thus, the susceptor 112 may provide a path to ground for electrons not only at the edge of the susceptor 112, but also at the middle of the susceptor 112. The path to ground at the middle of the susceptor 112 may balance out the path to ground at the edge of the susceptor 112 and the chamber walls 132 because each anode, be it the chamber walls 132 or the susceptor 112, may equally function as an anode and uniformly spread the plasma across the processing space 158. By uniformly distributing the plasma across the processing space 158, uniform deposition across the substrate may occur.

When the substrate is an insulating substrate (such as glass or polymer), the substrate is non-conductive and thus electrons do not follow through the substrate. As a consequence, when the insulating substrate substantially covers the substrate support, the substrate support does not provide sufficient anode surfaces near the center of the processing region 158. For large area substrates, such as solar panels or substrates for flat panel displays, the size of the substrate blocking the path to ground through the susceptor 112 may be significant. Substrates having an area as large as 1 square meter are not uncommon in the flat panel display industry. For a 1 square meter insulating substrate, a path to ground through the susceptor 112 is blocked for an area of 1 square meter. Therefore, the chamber walls 132 and the edges of the susceptor 112 that are not covered by the substrate are the only paths to ground for the electrons in the plasma. No path to ground exists near the center of the substrate. With a large area substrate, a high density plasma may form near the chamber walls 132 and the edge of the susceptor 112 that is not covered by the substrate. The high density plasma near the chamber walls 132 and the susceptor 112 edge may thin the plasma near the center of the processing region 158 where no path to ground exists. Without a path to ground near the center of the processing area 158, the plasma may not be uniform and hence, the deposition on the large area substrate may not be uniform.

To help provide uniform sputtering deposition across a substrate, an anode 134 may be disposed between the target 102 and the substrate (not shown). In one embodiment, the anode 134 may be bead blasted stainless steel coated with arc sprayed aluminum. In another embodiment, the anode 134 may be bead blasted. By bead blasting or arc spraying the anode 134, the anode 134 surface may be textured to capture material sputtered thereon and reduce any flaking or falling of material onto the substrate.

The anode 134 may be disposed a distance “A” from the target 102. The distance “A” may be small enough so as to reduce any shadowing of the substrate during deposition. The anode 134 may also be shaped to reduce any shadowing of the substrate and maximize deposition uniformity. The anode 134 may be sized to ensure that the anode 134 can support its own weight and the weight of the cooling fluid across the chamber. In one embodiment, the anode 134 may have a circular cross section. In another embodiment, the anode 134 may have an oblong cross section.

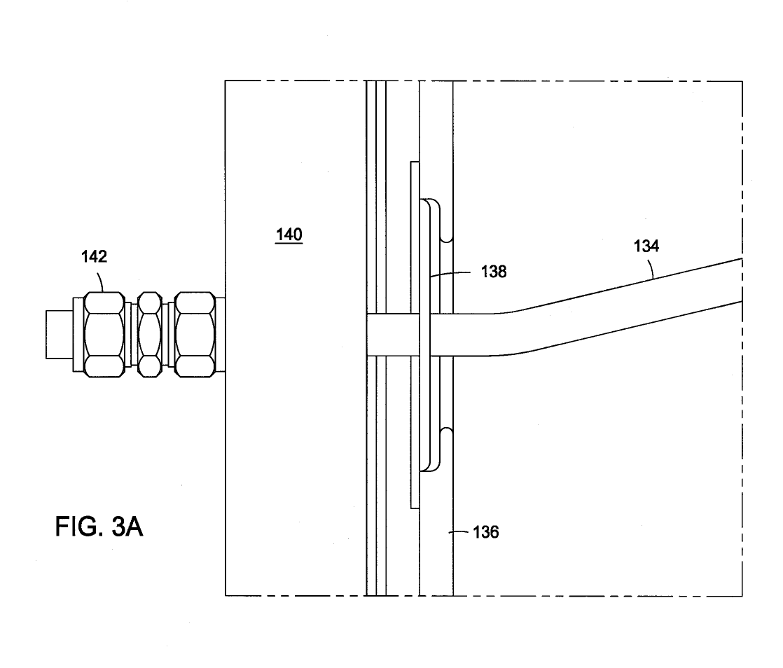

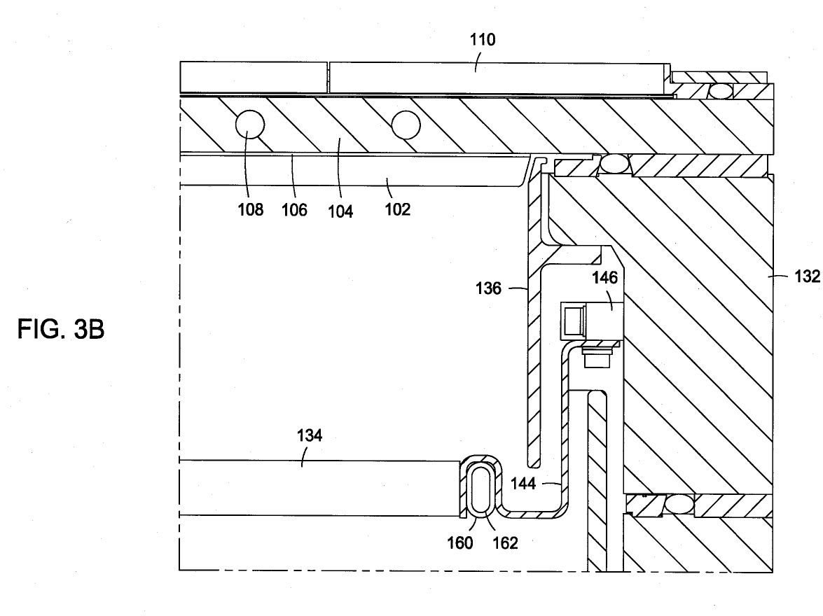

In one embodiment, one end of the anode 134 is mounted to the chamber wall 132 by a bracket 144 which may be coupled with a mounting ledge 146. As shown in FIG. 3B, the bracket 144 is shaped to partially enclose the anode 134 and shield a portion of the anode 134. The bracket 144 bends under the dark space shield 136. The bracket 144 may be coupled with a mounting ledge 146 via any conventional attachment device such as a screw or nut and bolt assembly. As shown in FIG. 1, a portion of the bracket 144 lies between the dark space shield 136 and the chamber shield 130. The bracket 144 may be coupled with an end of the anode 134 to ground the anode 134. The bracket 144 may be considered a flexible ground connection because the bracket 144, due to its potential exposure to plasma in the processing space 158, may expand and contract with temperature variations. The anode 134, while it is cooled, may also cool the bracket by conductive cooling 134.

The other end of the anode 134 passes through the dark space shield 136 and the chamber wall 132. As shown in FIG. 3A, a bracket 138 is coupled with the dark space shield 136 to couple the anode 134 with the dark space shield 136. At the end of the anode 134 is a connection assembly 142. The connection assembly 142 may be any conventionally known device for connecting fluid containing tubes together. An additional bracket 140 may couple the anode 134 to the chamber wall 132 and stabilize the connection assembly 142. The bracket 140 may provide a path to ground for the anode 134 and be fixed (i.e., relatively little expansion or contraction) due to is location that may be substantially hidden from the processing space 158. In another embodiment, the anode 134 may be mounted with an anchor mount, which may be shielded from deposition by an anode shield. The anchor mount may be positioned on the shield 116. The anchor mount may also provide a fixed path to ground similar to the bracket 140.

The anode 134 provides a charge in opposition to the target 102 so that charged ions will be attracted thereto rather than to the chamber walls 132 which are typically at ground potential. By providing the anode 134 between the target 102 and the substrate, the plasma may be more uniform, which may aid in the deposition.

When a substrate enters the apparatus 100, lift pins 114 rise up to receive the substrate. The lift pins 114 then lower and the susceptor 112 raises to receive the substrate. As the susceptor 112 raises to a processing position, the susceptor 112 encounters the shadow frame 118 and raises the shadow frame 118 up to a processing position with shadow frame lift pins 120. The shadow frame 118 reduces the amount of material that may deposit on exposed areas of the susceptor 112. When not raised, the shadow frame 120 rests on an under shield 122. The under shield 122 may be coupled with a cooling manifold 124.

Because the shadow frame 122 moves up and down, any material that deposits on the shadow frame 122 may flake off. To reduce flaking of material from the shadow frame 122, an additional shield 116, which is substantially stationary, may be positioned within the apparatus 100 to shield the shadow frame 122. Shield 116 is coupled with the cooling manifold 124. The cooling manifold 124 controls the temperature of the shield 116. Expansion and contraction of the shield 116 from temperature changes may cause flaking within the apparatus 100 and contaminate the substrate. By controlling the temperature of the shield 116, expansion and contraction of the shield 116 may be reduced. The cooling manifold 124 rests on a manifold shelf 126 and may be cooled by a cooling fluid that passes through cooling channels 128. The cooling fluid may be any conventional cooling fluid known to one of ordinary skill in the art.

By being within the processing space 158, material may deposit on the anode 134 during sputtering. Material deposited on the anode 134 may also be a source of contamination. During a sputtering process, the temperature may be significantly higher than during downtime. Changing the temperature of the anode 134 may lead to expansion and contraction of the anode 134 and hence, flaking of material deposited thereon. Additionally, the plasma temperature may be high enough to increase the temperature of the material deposited on the anode 134 to approach or reach its melting point. When the material deposited on the anode 134 reaches its melting point, the material may melt and hence, drip off of the anode 134 and onto the substrate. The flaking and dripping may be sources of contamination for the substrate.

To reduce flaking and material dripping, the anode 134 may be cooled. Cooling the anode 134 may control the temperature of the anode 134 and hence, reduce expansion and contraction of the anode 134 during processing and downtime. Additionally, cooling the anode 134 may reduce the material dripping. The cooled anode 134 cools any material that deposits on the anode 134 so that the temperature of the material does not approach its melting point. When the temperature of the material deposited on the anode 134 does not approach its melting point, dripping may be reduced.

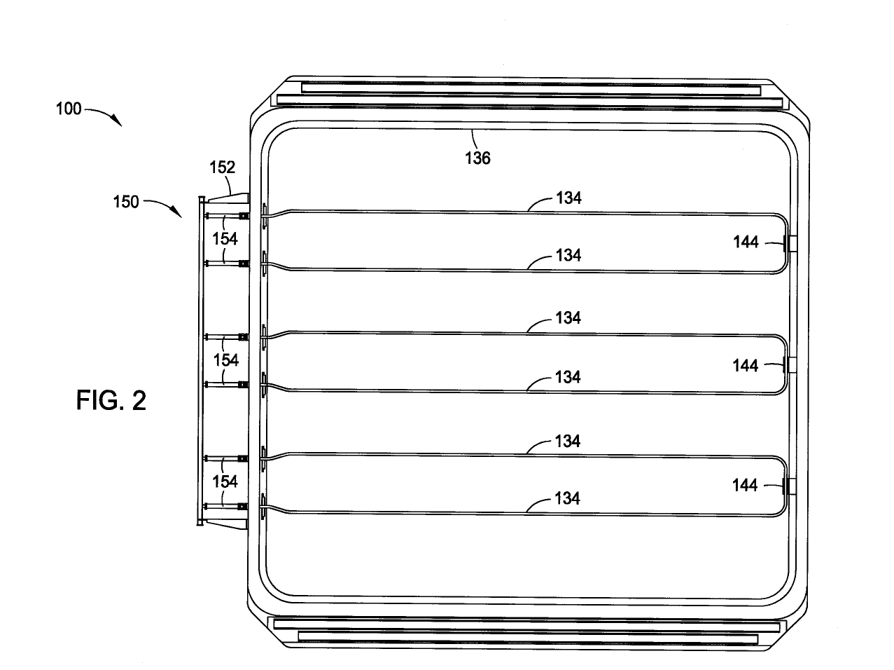

FIG. 2 is a top view of one embodiment of a PVD apparatus 100 incorporating three cooled anodes 134. It is to be understood that while three cooled anodes 134 are shown, more or less anodes 134 may be used. In the embodiment shown in FIG. 2, the anode 134 has a U-shape so that a single anode 134 spans the processing area 158 two times. Additionally, the cooling fluid may enter the anode 134 and exit the anode 134 on the same side of the apparatus 100. In another embodiment, the anode 134 may be substantially linear and span the processing area 158 one time.

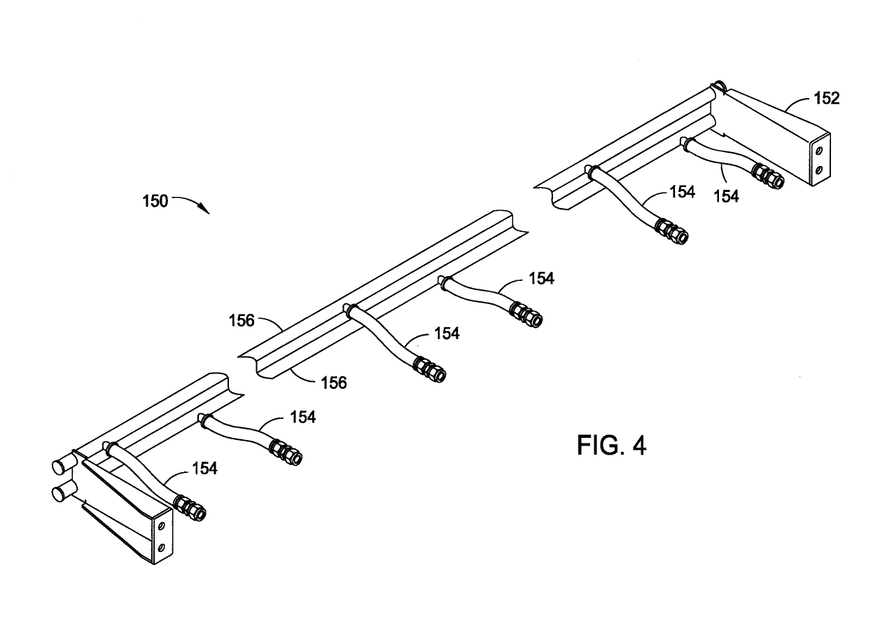

A cooling assembly 150 may be coupled to the apparatus 100 by a bracket 152. FIG. 4 shows the cooling assembly 150 according to one embodiment of the invention. The cooling assembly 150 may have inlet and outlet tubes 154 that couple with the connection assembly 142 to circulate cooling fluid to and from the cooling feed/withdrawal tubes 156. The cooling fluid that passes through the anodes 143 remains within the anodes 134 and may not enter the processing environment. The cooling fluid flows within the inner walls 162 of the anode 134 and does not pass through the inner wall 162 to the outer wall 160. The outer wall 160 of the anode 134 is exposed to the processing environment. By flowing the cooling fluid through the anode 134 itself, additional cooling channels or tubes within the anode 134 or on the anode 134 may not be necessary. The cooling fluid may be any conventional cooling fluid known to one of ordinary skill in the art.

While the invention has been described above with reference to a target 102, it is to be understood that multiple targets may be present. For example, large area targets necessary to sputter deposit on large area substrates can be quite expensive. Therefore, multiple targets with small gaps therebetween may be spaced across a backing plate. The multiple targets are smaller than one large area target, but may essentially function as a single large area target. Examples of such targets are disclosed in United States Patent Publication No. 2007/0056850, U.S. patent application Ser. No. 11,424,467, filed Jun. 15, 2006, and U.S. patent application Ser. No. 11/424,478, filed Jun. 15, 2006, all of which are hereby incorporated by reference in their entirety.

The targets 102 that may be used are not limited to square shaped targets. Target strips and target tiles are examples of other suitable targets 102 that may be used to practice the invention. For non-square shaped targets 102, the anodes 134 may span the processing space 158 in the direction of the longest edge of the target 102. In another embodiment, the anodes 134 may span the processing space in a direction perpendicular to the longest edge of the target 102.

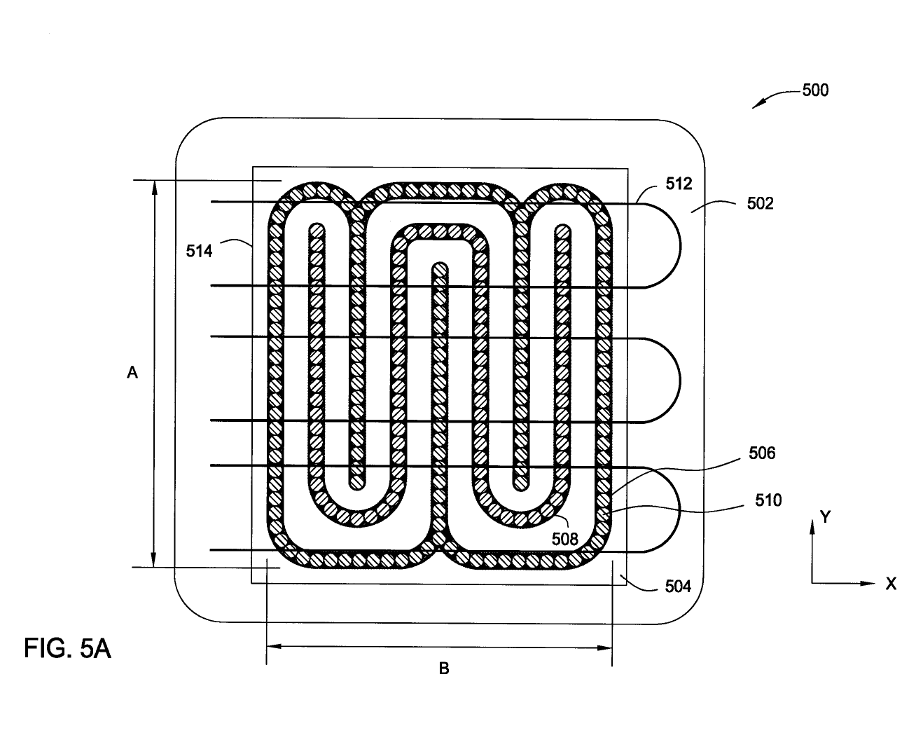

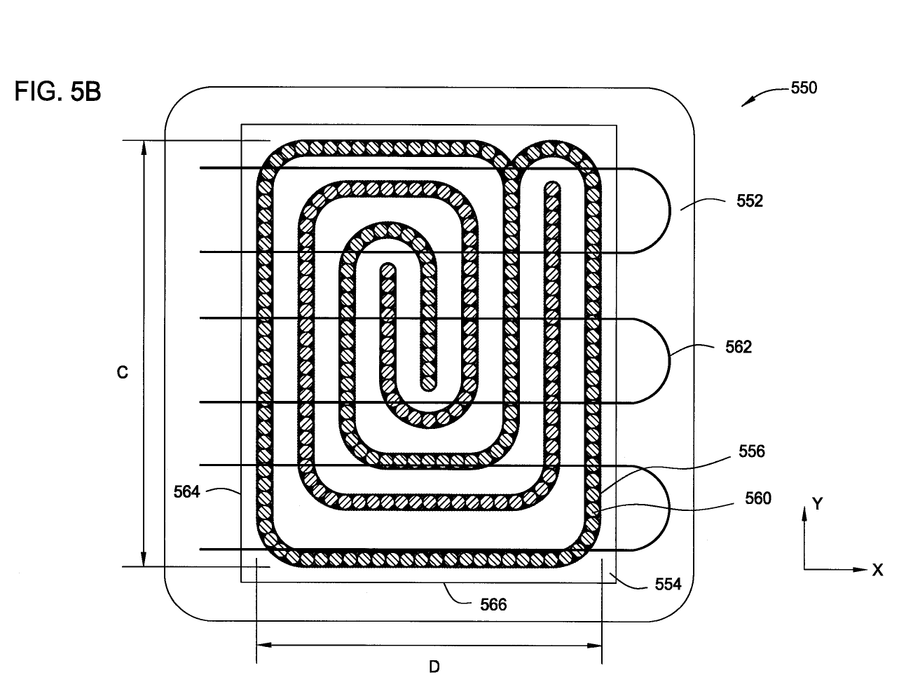

FIGS. 5A and 5B are schematic views of magnetrons in relation to cooled anodes according to embodiments of the invention. FIG. 5A shows an apparatus 500 having a magnetron assembly 504 disposed behind a backing plate 502. The magnetron assembly 504 comprises an outer groove 506 and an inner groove 508 in which a plurality of magnets 510 may be disposed. The outer groove 506 may contain magnets 510 having a first polarity while the inner groove 508 may contain magnets 510 having a different polarity such that a magnetic field may form between the grooves 506, 508. One or more anodes 512 may be disposed across the processing chamber. The anodes 512 may be perpendicular to the long side 514 of the magnetron assembly 504. The long side 514 of the magnetron assembly 504 may have a length “A” while the short side 516 may have a length “B” where “A”>“B”.

Similar to FIG. 5A, FIG. 5B shows an apparatus 550 having a magnetron assembly 554 disposed behind a backing plate 552 in which the magnetron assembly 554 comprises an outer groove 556 and an inner groove 558 in which a plurality of magnets 560 may be disposed. The magnetron assembly 554 of FIG. 5B has a different serpentine layout compared to FIG. 5A. The outer groove 556 may contain magnets 560 having a first polarity while the inner groove 558 may contain magnets 560 having a different polarity such that a magnetic field may form between the grooves 556, 558. One or more anodes 562 may be disposed across the processing chamber. The anodes 562 may be perpendicular to the long side 564 of the magnetron assembly 554. The long side 564 of the magnetron assembly 554 may have a length “C” while the short side 516 may have a length “D” where “C”>“D”.

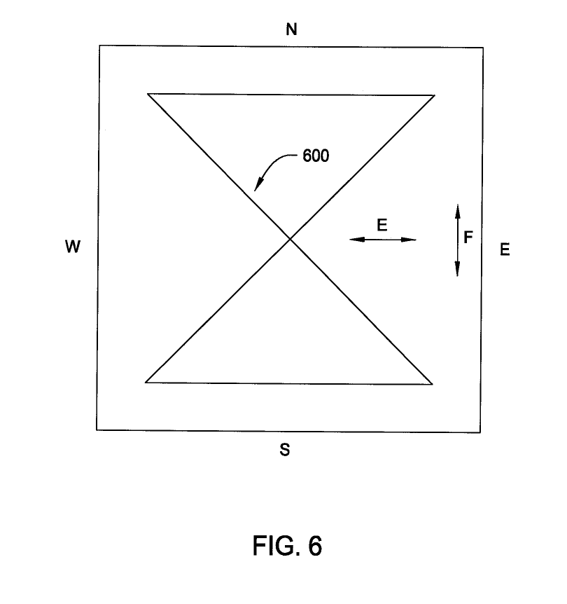

To prevent localized heating of the anode and to ensure uniform target erosion, the magnetron assembly may be scanned across the backing plate. FIG. 6 is a schematic view of a scanning pattern 600 for a magnetron according to one embodiment of the invention. In one embodiment, the magnetron may additionally move laterally as shown by arrow F and/or horizontally as shown by arrow E. The lateral and/or horizontal movement of the magnetron assembly may be in addition to the scanning pattern 600. By scanning the magnetron assembly, the magnetic field may be moved across the sputtering target so that the sputtering target may uniformly erode. Additionally, the high density plasma within the magnetic field in front of the sputtering target may be moved during scanning such that the high density plasma does not remain concentrated over any particular area of the anodes spanning the processing space. Thus, scanning the magnetron assembly and hence, the magnetic field, may prevent localized heating of the anodes.

For large area substrates, it is beneficial to provide a path to ground in the middle of the processing area so that uniform deposition may occur. An anode that spans the processing area between the target and the substrate may provide the path to ground for electrons within the plasma to increase uniform plasma distribution across the processing space and hence, uniform deposition on the substrate. Cooling the anode may reduce flaking and material dripping.

While the foregoing is directed to embodiments of the present invention, other and further embodiments of the invention may be devised without departing from the basic scope thereof, and the scope thereof is determined by the claims that follow.

1. A physical vapor deposition apparatus, comprising:
a chamber body having a processing space therein;
one or more targets;
a substrate support; and
one or more anodes positioned between the one or more targets and the substrate support, the one or more anodes each comprising an inner and outer wall, wherein the inner wall defines a fluid flow path through which cooling fluid flows while in contact with the inner wall.

2. The apparatus of claim 1, further comprising:
a bracket coupled with each anode, wherein the bracket is shaped to suspend the anode therefrom.

3. The apparatus of claim 2, wherein the bracket is coupled to ground.

4. The apparatus of claim 1, wherein the one or more anodes comprise a roughened surface.

5. The apparatus of claim 1, wherein at least one anode of the one or more anodes comprises a U-shaped structure.

6. The apparatus of claim 1, further comprising:
a magnetron having a first segment having a first length and a second segment having a second length less than the first length, wherein the one or more anodes extend across the processing space substantially perpendicular to the first segment.

7. The apparatus of claim 6, wherein the magnetron is movable relative to the one or more targets.

8. The apparatus of claim 6, wherein the magnetron is movable is two dimensions.

9. The apparatus of claim 1, wherein at least one anode of the one or more anodes passes through the processing space a plurality of times.

10. The apparatus of claim 1, wherein the one or more anodes are coupled to a fixed grounding element.

11. The apparatus of claim 10, wherein the one or more anodes are coupled to a flexible grounding element.

12. An anode assembly, comprising:
an anode body having an outer wall, a hollow passage bounded by an inner wall, a first end having a cooling fluid inlet coupled thereto, and a second end having a fluid outlet coupled thereto.

13. The anode assembly of claim 12, wherein the anode body comprises a U-shaped structure.

14. The anode assembly of claim 12, further comprising a bracket coupled with the anode body.

15. The anode assembly of claim 12, wherein the outer wall comprises a roughened surface.

16. A physical vapor deposition method, comprising:
positioning a susceptor within a chamber opposite a sputtering target to define a processing space between the target and the susceptor;
sputtering material from the target to create a plasma;
providing a path to ground within the processing space, the path to ground spanning an area across the processing space and comprising an inner wall and an outer wall; and
flowing a cooling fluid within the path to ground while in contact with the inner wall.

17. The method of claim 16, wherein a magnetron is disposed behind the sputtering target, the magnetron comprising a first segment having a first length and a second segment having a second length less than the first length, the method further comprising:
flowing the cooling fluid perpendicular to the first segment.

18. The method of claim 17, further comprising translating the magnetron behind the sputtering target.

19. The method of claim 18, wherein the magnetron is translated in two dimensions.

20. The method of claim 16, further comprising:
creating a magnetic field extending into the processing space; and
moving the magnetic field.

21. The method of claim 16, wherein the cooling fluid enters and exits the path to ground through a same side of the chamber.

22. The method of claim 16, wherein the path to ground comprises an anode having a roughened surface.
